(19) United States
(12) Patent Application Publication
(10) Pub. No.: US 2016/0020099 A1
(43) Pub. Date: Jan. 21, 2016

(54) PATTERN FORMING METHOD AND METHOD OF MANUFACTURING SEMICONDUCTOR DEVICE

(71) Applicant: Kabushiki Kaisha Toshiba, Minato-ku (JP)

(72) Inventors: Kazuhiro SEGAWA, Kuwana (JP); Nobuhiro KOMINE, Nagoya (JP); Kentaro MATSUNAGA, Yokkaichi (JP); Takehiro KONDOH, Yokkaichi (JP); Shinichi NAKAGAWA, Yokohama (JP)

(73) Assignee: Kabushiki Kaisha Toshiba, Minato-ku (JP)

(21) Appl. No.: 14/572,908

(22) Filed: Dec. 17, 2014

Related U.S. Application Data
(60) Provisional application No. 62/026,725, filed on Jul. 21, 2014.

(51) Int. Cl. H01L 21/033; H01L 21/3213; H01L 29/40; H01L 29/423

(52) U.S. Cl. CPC H01L 21/0338; H01L 29/42324; H01L 21/32139; H01L 21/0332; H01L 21/0335; H01L 21/0337; H01L 29/401

(57) ABSTRACT

According to one embodiment, first, an embedment material is embedded between linear core material patterns in such a manner that a height thereof becomes lower than a height of each of the core material patterns. Then, a shrink agent is supplied and solidified on the embedment material. Subsequently, the solidified shrink agent and the embedment material are removed and a spacer film is formed on an object of processing. Then, the spacer film is etched-back and a spacer pattern is formed by removal of the core material patterns. The solidified shrink agent which is formed in such a manner that a width of the spacer pattern becomes narrow in a region corresponding to a position where the shrink agent, in a sectional surface vertical to an extended direction of the spacer pattern is supplied is removed.

### CROSS-REFERENCE TO RELATED APPLICATIONS

This application is based upon and claims the benefit of priority from U.S. Provisional Application No. 62/026,725, filed on Jul. 21, 2014; the entire contents of which are incorporated herein by reference.

### FIELD

Embodiments described herein relate generally to a pattern forming method and a method of manufacturing a semiconductor device.

### BACKGROUND

Currently, in a lithography process, a patterning method using a sidewall transfer process is used to form a pattern equal to or below a resolution limit of optical lithography technique. In the sidewall transfer process, first, a core material having a predetermined shape is formed above a film to be processed. Then, a sidewall film is formed around the core material and the sidewall film is etched-back in such a manner that an upper surface of the core material is exposed. Then, the core material is removed. By the above process, a sidewall pattern is formed. Then, with the sidewall pattern as a mask, the film to be processed, which is a base, is processed and a pattern is formed.

In a conventional patterning method, a pattern defect such as a sidewall pattern collapse or sidewall patterns sticking to each other during a removal of a core material in a case where a pattern pitch is narrow has not been considered.

### BRIEF DESCRIPTION OF THE DRAWINGS

FIG. 1 is an equivalent circuit diagram illustrating a part of a memory cell array formed in a memory cell region of an NAND-type flash memory device;

FIG. 2 is a plane view illustrating a layout pattern of a part of the memory cell region;

FIG. 3 is an A-A sectional view of FIG. 2;

FIG. 4A to FIG. 4K are partial sectional views schematically illustrating an example of a pattern forming method according to a first embodiment;

FIG. 5A to FIG. 5C are partial sectional views schematically illustrating an example of a pattern forming method according to a second embodiment; and

FIG. 6A to FIG. 6H are partial sectional views schematically illustrating an example of a pattern forming method according to a third embodiment.

### DETAILED DESCRIPTION

In general, according to one embodiment, a pattern forming method is provided. First, linear core material patterns arranged vertically to an extended direction at predetermined intervals are formed on an object of processing. Subsequently, between the core material patterns, an embedment material is embedded in such a manner that a height thereof becomes lower than a height of each of the core material patterns. Then, a shrink agent is supplied on the embedment material between the core material patterns. Subsequently, the shrink agent is heated and solidified. Then, at least a part of the solidified shrink agent and the embedment material are removed. Subsequently, a spacer film is formed on the object of processing on which the core material patterns are formed. Then, the spacer film is etched-back in such a manner that upper surfaces of the core material patterns are exposed. Then, the core material patterns are removed and a spacer pattern including the spacer film is formed. In the removal of the solidified shrink agent and the embedment material, the solidified shrink agent which is formed in such a manner that a width of the spacer pattern becomes narrow in a region corresponding to a position where the shrink agent is supplied, in a sectional surface vertical to an extended direction of the spacer pattern is removed.

In the following, a pattern forming method and a method of manufacturing a semiconductor device according to an embodiment will be described in detail with reference to the attached drawings. Note that the present invention is not limited to these embodiments. Also, sectional views of a semiconductor device which views are used in the following embodiments are schematic. A relationship between a thickness and a width of a layer, a thickness ratio of each layer, and the like may be different from actual ones.

### First Embodiment

In the following, a case where an embodiment is applied to a method of manufacturing an NAND-type flash memory device as a semiconductor device will be described. The NAND-type flash memory device includes a memory cell region and a peripheral circuit region. The memory cell region is a region in which a great number of memory cell transistors (hereinafter, also referred to as memory cell) are arranged in a matrix. The peripheral circuit region is a region including a peripheral circuit transistor to drive the memory cells.

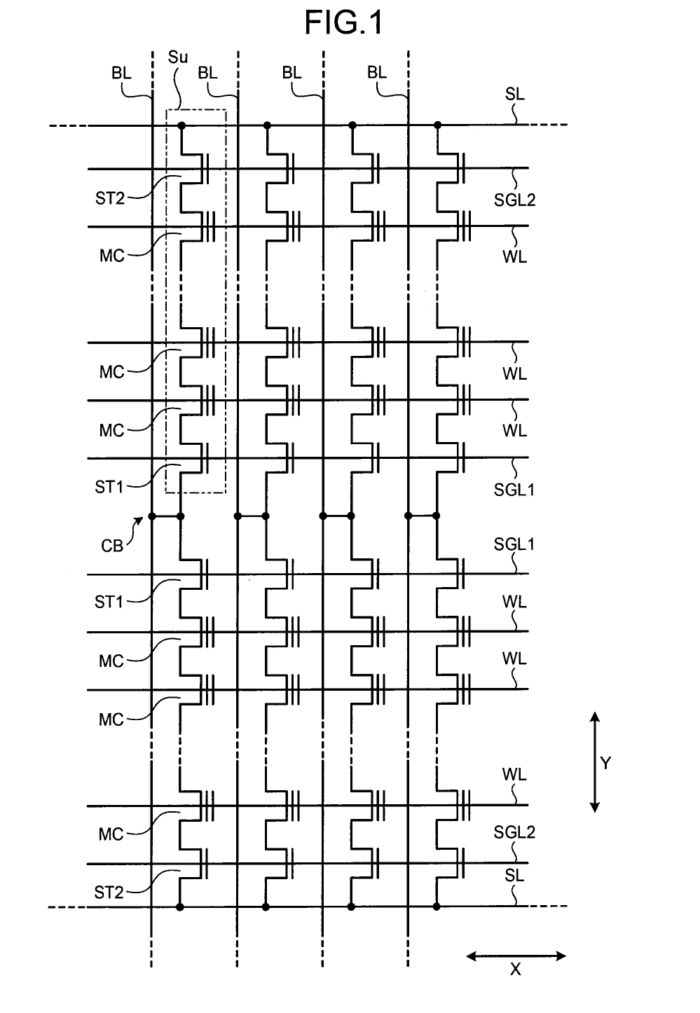

FIG. 1 is an equivalent circuit diagram illustrating a part of a memory cell array formed in the memory cell region of the NAND-type flash memory device. The memory cell array of the NAND-type flash memory device includes a structure in which NAND cell units (memory unit) Su are arranged in a matrix. Each of the NAND cell units Su includes two selection gate transistors ST1 and ST2 and a memory cell column. The memory cell column includes a structure in which a plurality of (for example, nth power of 2 pieces (n is positive integer)) memory cells MC is arranged in series between the two selection gate transistors ST1 and ST2. In each of the NAND cell units Su, the plurality of memory cells MC is formed, adjoining memory cells sharing a source/drain region.

The memory cells MC arrayed in an X direction (corresponding to word line direction and gate width direction) in FIG. 1 are connected in common by a word line (control gate line) WL. Also, the selection gate transistors ST1 arrayed in the X direction in FIG. 1 are connected in common by a selection gate line SGL1 and the selection gate transistors ST2 are connected in common by a selection gate line SGL2. To a drain region of each of the selection gate transistors ST1, a bit line contact CB is connected. One end of the bit line contact CB is connected to a bit line BL extended in a Y direction (corresponding to bit line direction and gate length direction) orthogonal to the X direction in FIG. 1. Also, each of the selection gate transistors ST2 is connected to a source line SL extended in the X direction in FIG. 1 through a source region.

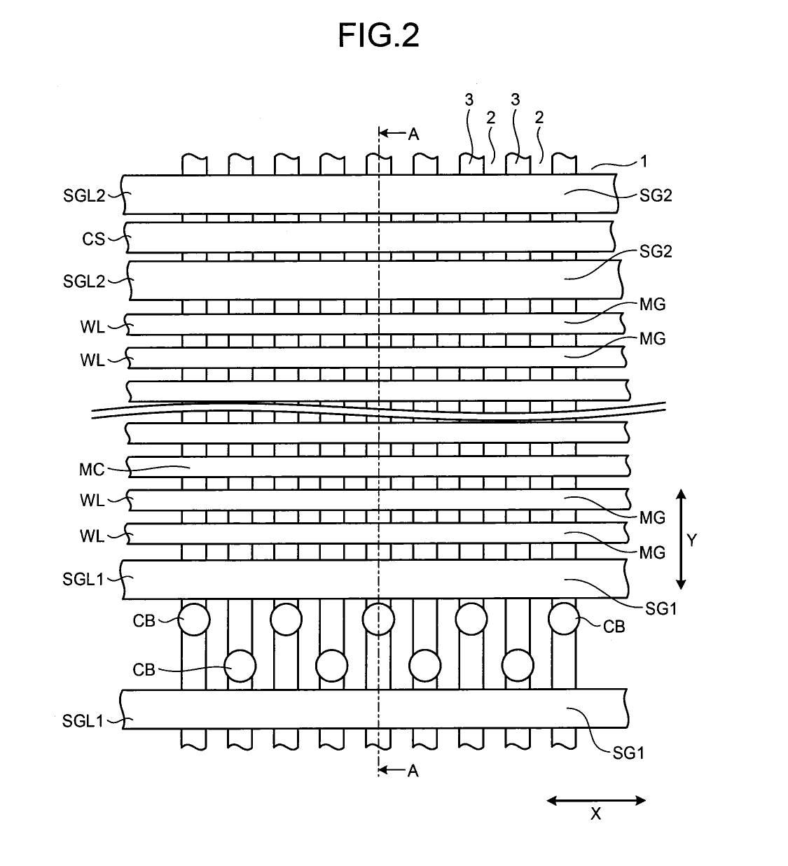

FIG. 2 is a plane view illustrating a layout pattern of a part of the memory cell region. In a semiconductor substrate 1, a plurality of pieces of shallow trench isolation (STI) 2 as an element isolation region is extended in a Y direction in FIG. 2 and is formed at predetermined intervals in an X direction. Adjoining active regions 3 are separated in the X direction in FIG. 2 by the STI 2. The word lines WL of the memory cells MC are extended in the X direction in FIG. 2, which direction is orthogonal to the active regions 3, and are formed in a line-and-space manner at predetermined intervals in the Y direction.

Also, the two selection gate lines SGL1 extended in the X direction in FIG. 2 are formed in parallel and in an adjoining manner. In the active regions 3 between the two adjoining selection gate lines SGL1, the bit line contacts CB are respectively formed. In this example, the bit line contacts CB are arranged in such a manner that positions thereof in the Y direction are alternately changed in the adjoining active regions 3. Specifically, between the two selection gate lines SGL1, there are the bit line contact CB arranged closer to a side of one selection gate line SGL1 and the bit line contact CB arranged closer to a side of the other selection gate line SGL1. That is, the bit line contacts CB are arranged in a zigzag manner.

To a position where the selection gate lines SGL1 and a predetermined number of word lines WL are arranged, the two selection gate lines SGL2 extended in the X direction in FIG. 2 are formed in parallel similarly to a case of the selection gate lines SGL1. Then, in the active regions 3 between the two selection gate lines SGL2, a source line contact CS is arranged.

On the active regions 3 which intersect with the word lines WL, stacked gate structures MG of the memory cells MC are formed. Also, on the active regions 3 which intersect with the selection gate lines SGL1 and SGL2, gate structures SG1 and SG2 of the selection gate transistors ST1 and ST2 are formed.

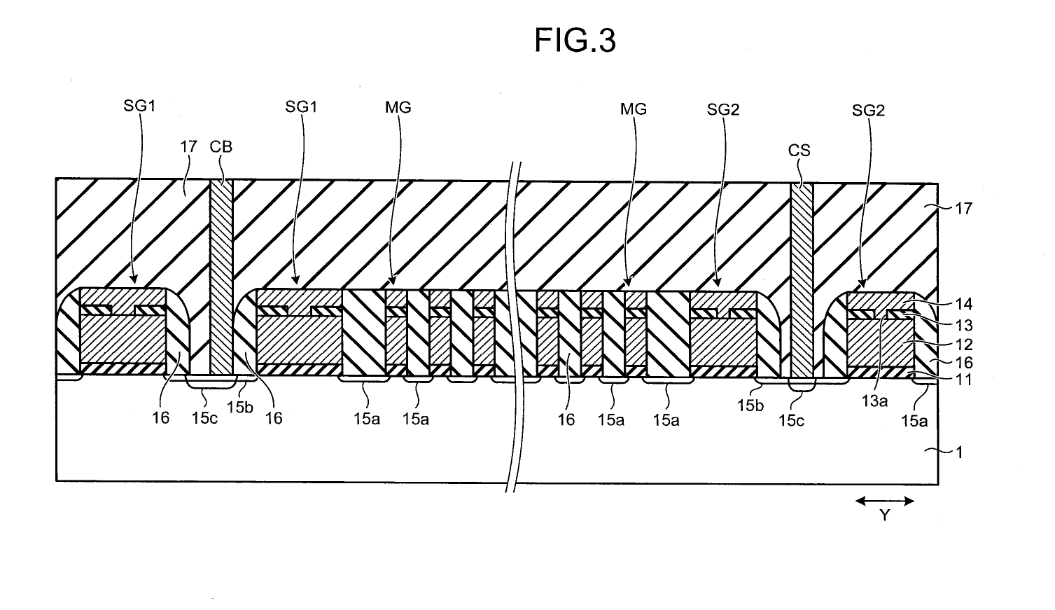

FIG. 3 is an A-A sectional view of FIG. 2. That is, the gate structures SG1 and SG2 of the selection gate transistors ST1 and ST2 and the stacked gate structures MG of the memory cells MC arranged between the two selection gate transistors ST1 and ST2 in one of the active regions 3 are illustrated. In FIG. 3, each of the stacked gate structures MG of the memory cells MC and the gate structures SG1 and SG2 of the selection gate transistors ST1 and ST2 includes a structure in which a floating gate electrode film 12, an inter-electrode insulation film 13, and a control gate electrode film 14 are arranged serially on the semiconductor substrate 1 via a tunnel insulation film 11. Note that in the inter-electrode insulation film 13 of each of the gate structures SG1 and SG2 of the selection gate transistors ST1 and ST2, an opening 13a is formed. Into the opening 13a, the control gate electrode film 14 is embedded. Thus, the floating gate electrode film 12 and the control gate electrode film 14 are conducted to each other. In such a manner, in each of the selection gate transistors ST1 and ST2, a gate electrode is configured by the floating gate electrode film 12 and the control gate electrode film 14.

As the semiconductor substrate 1, a silicon substrate or the like can be used. As the tunnel insulation film 11, a thermal oxide film, a thermal oxynitride film, a chemical vapor deposition (CVD) oxide film, a CVD oxynitride film, an insulation film in which Si is sandwiched, an insulation film into which Si is embedded in a dot-shape, or the like can be used. As the floating gate electrode film 12, polycrystalline silicon to which an N-type impurity or a P-type impurity is doped, a metal film or a polymetal film including Mo, Ti, W, Al, Ta or the like, a nitride film, or the like can be used. As the inter-electrode insulation film 13, a silicon oxide film, a silicon nitride film, an oxide-nitride-oxide (ONO) film which is a stacked structure of silicon oxide films and a silicon nitride film, a high dielectric constant film such as an aluminum oxide film or a hafnium oxide film, a stacked structure of a low dielectric constant film such as a silicon oxide film or a silicon nitride film and a high dielectric constant film, or the like can be used. As the control gate electrode film 14, polycrystalline silicon to which an N-type impurity or a P-type impurity is doped, a metal film or a polymetal film including Mo, Ti, W, Al, Ta or the like, a stacked structure of a polycrystalline silicon film and a metal silicide film, or the like can be used.

Near a surface of the semiconductor substrate 1 between the stacked gate structures MG-MG and between the stacked gate structure MG and the gate structures SG1 and SG2, impurity diffusion regions 15a to be source/drain regions are respectively formed. Also, near the surface of the semiconductor substrate 1 between the adjoining gate structures SG1-SG1 and between SG2-SG2, impurity diffusion regions 15b to be source/drain regions similarly to the impurity diffusion regions 15a are respectively formed.

On each sidewall surface between the pair of adjoining stacked gate structures MG-MG, between the stacked gate structure MG and the gate structures SG1 and SG2, between the gate structures SG1-SG1, and between the gate structures SG2-SG2, for example, a sidewall insulation film 16 including a silicon oxide film is formed. Between the stacked gate structures MG-MG and between the stacked gate structure MG and the gate structures SG1 and SG2, the sidewall insulation films 16 are respectively formed in an embedded manner. On the other hand, between the gate structures SG1-SG1 and between the gate structures SG2-SG2, the sidewall insulation films 16 are not entirely embedded and the sidewall insulation films 16 are formed in such a manner as to be provided to opposing sidewall surfaces.

Near the surface of the semiconductor substrate 1 between the opposing sidewall insulation films 16 between the gate structures SG1-SG1 and between the gate structures SG2-SG2, impurity diffusion regions 15c to reduce a contact resistance of the bit line contact CB or the source line contact CS are respectively formed. Each of the impurity diffusion regions 15c is formed with a narrow width and a deep diffusion depth (depth of pn junction) compared to the impurity diffusion regions 15b and has a lightly doped drain (LDD) structure.

Also, on the stacked gate structures MG and the gate structures SG1 and SG2 on which the sidewall insulation films 16 are formed, an interlayer insulation film 17 is formed. Between the adjoining gate structures SG1-SG1 arranged to one end of a column of the memory cells MC, a bit line contact CB is formed from an upper surface of the interlayer insulation film 17 to the surface of the semiconductor substrate 1. As described, in a planer view, the bit line contacts CB are arranged alternately in a zigzag manner. In a case of FIG. 3, a bit line contact CB is arranged to a position closer to a right side. Also, between the adjoining gate structures SG2-SG2 arranged to the other end of the column of the memory cells MC, a source line contact CS is formed from the upper surface of the interlayer insulation film 17 to the surface of the semiconductor substrate 1 in such a manner as to cross a lower part of the bit line BL. Note that a structure of the memory cells MC illustrated in FIG. 3 is an example and a different structure may be included.

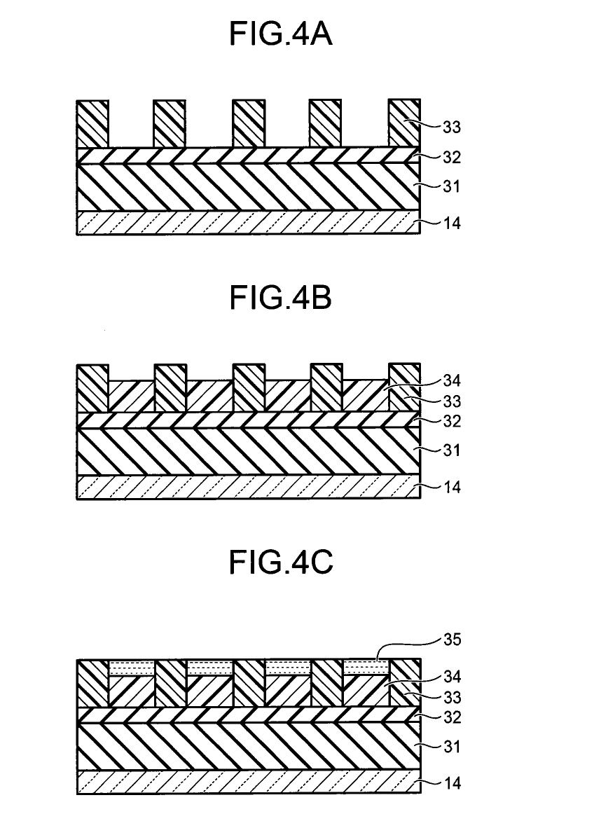

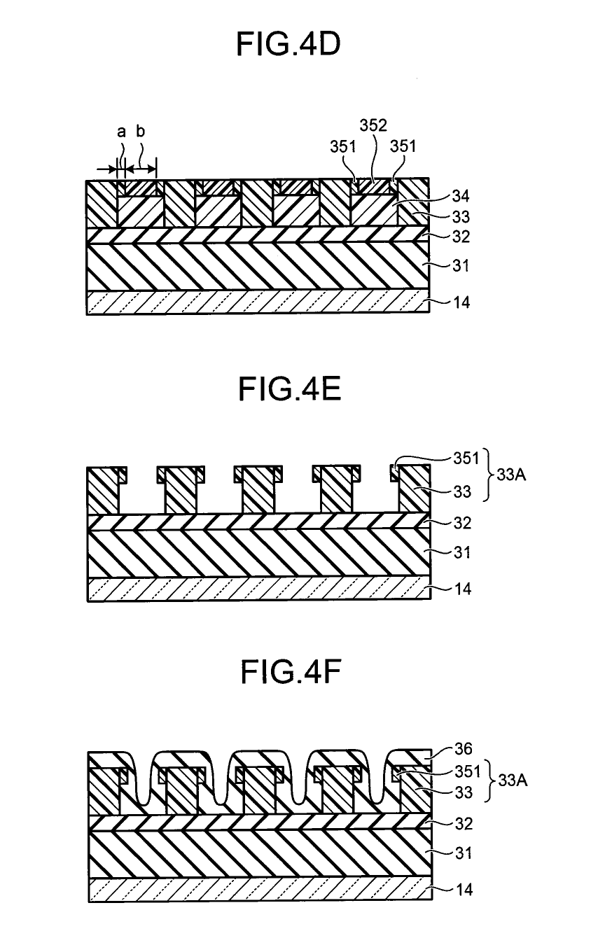

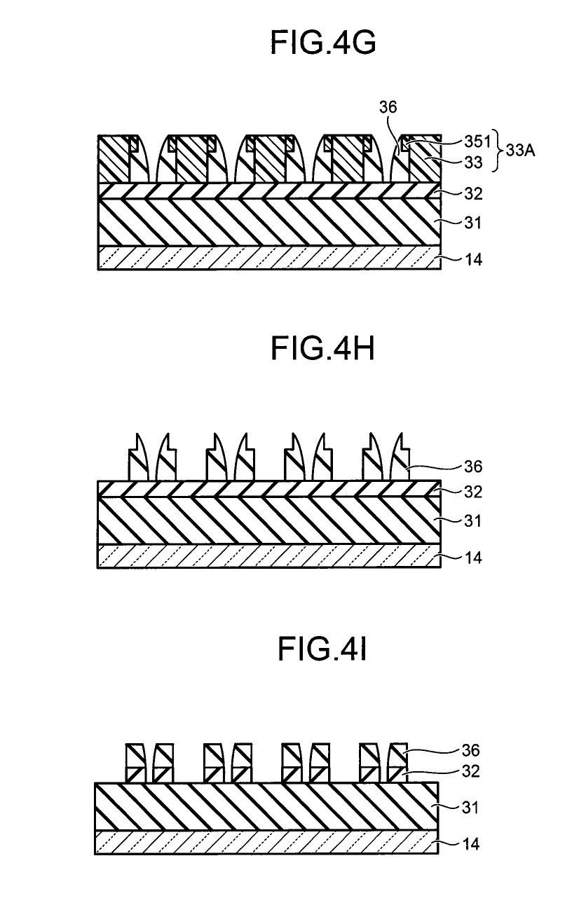

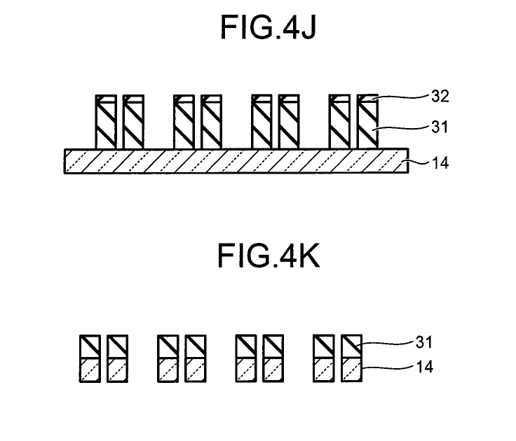

Then, a pattern forming method and a method of manufacturing a semiconductor device will be described with a case of forming an NAND-type flash memory device as an example. FIG. 4A to FIG. 4K are partial sectional views schematically illustrating an example of a pattern forming method according to the first embodiment. Note that here, a partial region in which a line-and-space word line WL between the selection gate lines SGL1 and SGL2 (hereinafter, referred to as SGL) of one memory unit Su is arranged is illustrated.

First, on a predetermined conductive semiconductor substrate, a tunnel insulation film and a floating gate electrode film are formed and trenches which reach the semiconductor substrate are formed by photolithography technique and by etching technique such as a reactive ion etching (RIE) method. The trenches are extended in the Y direction (bit line direction) and are formed at predetermined intervals in the X direction (word line direction). Subsequently, an insulation film such as a silicon oxide film is embedded into the trench and an STI is formed. Then, above a whole surface of the semiconductor substrate, an inter-electrode insulation film is formed. Then, by using the photolithography technique and the etching technique, an opening which penetrates the inter-electrode insulation film is formed in a formation region of the selection gate lines SGL1 and SGL2. Then, above the whole surface of the semiconductor substrate, the control gate electrode film 14 is formed. Note that objects of processing in this example are a tunnel insulation film, a floating gate electrode film, an inter-electrode insulation film, and a control gate electrode film 14 formed on the semiconductor substrate. However, in the following sectional views, only the control gate electrode film 14 on the top layer will be illustrated and described as the object of processing. Also, it is assumed that Si is used as the control gate electrode film 14.

Then, as illustrated in FIG. 4A, on a whole surface of the object of processing (control gate electrode film 14), a hard mask layer 31 and an antireflection film 32 are stacked in order. As the hard mask layer 31, for example, a spin on carbon (SOC) film can be used and as the antireflection film 32, a spin on glass (SOG) film can be used. Moreover, a resist is applied on the antireflection film 32 and the resist is patterned by the lithography technique in such a manner that a line-and-space pattern (periodic pattern) is included, whereby a core material pattern 33 is formed. Here, patterning is performed in such a manner that line patterns extended in the X direction are arranged at predetermined intervals in the Y direction. That is, the core material pattern 33 includes a line-and-space resist pattern.

Then, as illustrated in FIG. 4B, on the antireflection film 32 between the core material patterns 33, an embedment material 34 is formed. The embedment material 34 is preferably an organic material which can be removed in a developing process. Specifically, a polymer which is the same with a polymer chain, in a block copolymer used in a later process, having low affinity for the core material pattern 33 can be used. As the embedment material 34, for example, polymethylmethacrylate (PMMA) can be used. The embedment material 34 is formed in such a manner that a height of the embedment material 34 becomes lower than a height of the core material patterns 33.

Then, as illustrated in FIG. 4C, on the embedment material 34 between the core material patterns 33, a shrink agent 35 is applied. In the first embodiment, as the shrink agent, a solution including a block copolymer is used. Specifically, by a method such as an ink jet method, a solution in which a block copolymer is dissolved is discharged on the embedment material 34 between the core material patterns 33 and spin rotation is performed. Accordingly, on the embedment material 34 between the core material patterns 33, the solution including a block copolymer is applied uniformly.

Here, the block copolymer includes a structure in which a plurality of kinds of polymer chains is combined. Each polymer chain includes one kind of chain structure of a monomer. The block copolymer used in the first embodiment includes a structure in which a polymer chain having high affinity and a polymer chain having low affinity are combined. As such a block copolymer, polystyrene-polymethylmethacrylate (hereinafter, referred to as Ps-b-PMMA) including a polystyrene derivative and polymethylmethacrylate (acrylic) can be used. According to a degree of projection in a lateral direction of an upper part of each core material pattern 33, a molecular weight and composition of the block copolymer can be determined.

Then, the object of processing is heated in a hot plate of a nitrogen atmosphere at 240° C. for 60 seconds, for example. Accordingly, as illustrated in FIG. 4D, in the block copolymer in the solution, the same kind of polymer chains are aggregated and a block (phase) including the same kind of polymer chains is formed. During the phase separation, what having high affinity in the block copolymer is attracted to a side of each core material pattern 33. Thus, when Ps-b-PMMA is used as the block copolymer, a polystyrene derivative is attracted to the side of each core material pattern 33. That is, on a side of a side wall in an upper part of each core material pattern 33, an adherence portion 351 in which a polymer chain (Ps) having high affinity is aggregated is formed. Also, near a center between the core material patterns 33, a sacrifice portion 352 in which a polymer chain (PMMA) having low affinity is aggregated is formed. Also, the sacrifice portion 352 and the embedment material 34 include the same high polymer material.

It is assumed that a thickness of the adherence portion 351 adhered to each core material pattern 33 is a and a thickness of the sacrifice portion 352 is b. Here, a≠0 or b≠0.

Subsequently, as illustrated in FIG. 4E, the embedment material 34 and the sacrifice portion 352 aggregated near a center in an upper part thereof are selectively removed. For example, the embedment material 34 and the sacrifice portion 352 are removed by developing processing. Here, a solvent including an organic solvent which can dissolve polymethylmethacrylate (acrylic) included in the embedment material 34 and the sacrifice portion 352 is used as a developer.

As a result, by each core material pattern 33 and the adherence portion 351 remaining around the upper part thereof, a new core material pattern 33A is formed. In a sectional surface vertical to an extended direction of the new core material pattern 33A, an upper part has a wider width than a lower part. That is, the core material pattern 33A includes a structure in an upper part of which an eave-shaped pattern is formed.

Then, as illustrated in FIG. 4F, on the antireflection film 32 and the core material pattern 33A, a spacer (side wall) film 36 is formed. The spacer film 36 is formed to cover the core material patterns 33A in a conformal manner. To prevent the core material pattern 33A (resist pattern) from being thermally denatured during the formation of the spacer film 36, the spacer film 36 is preferably formed at a low temperature, for example, in a range of 25 to 100° C. As the spacer film 36, a low temperature oxide film, a low temperature nitride film, an amorphous silicon film, a carbon film, or the like can be used.

Then, as illustrated in 4G, the spacer film 36 is etched-back by anisotropic etching of an RIE method or the like until an upper surface of the core material pattern 33A and an upper surface of the antireflection film 32 between the core material patterns 33A are exposed. Accordingly, the spacer film 36 having a looped shape is formed around the core material pattern 33A.

Then, as illustrated in FIG. 4H, the core material pattern 33A is removed, for example, by organic material removing technique (asher) using an oxygen radical. Since the core material pattern 33A is an organic film, ashing is performed by the oxygen radical. By making the core material pattern 33A include the eave-shaped pattern, possibility of collapse of the spacer film 36 can be reduced even when the core material pattern 33A is removed. As a result, on the antireflection film 32, the looped spacer film 36 (spacer pattern) remaining in a state substantially vertical to a substrate surface (surface of antireflection film 32) is formed.

Then, as illustrated in FIG. 4I, with the spacer film 36 as a mask, the antireflection film 32 is processed by the anisotropic etching of the RIE method or the like. Accordingly, a looped pattern is transferred to the antireflection film 32.

Then, as illustrated in FIG. 4J, with the patterned antireflection film 32 as a mask, the hard mask layer 31 is processed by the anisotropic etching of the RIE method or the like. Accordingly, a looped pattern is transferred to the hard mask layer 31. Also, the antireflection film 32 and the hard mask layer 31 form a mask pattern in which looped patterns are arranged at predetermined intervals in the Y direction, each of the looped patterns being a pair of line patterns extended in the X direction, both ends of which are respectively connected to each other.

Note that as illustrated in FIG. 4H, since the spacer film 36 includes a structure which stands vertical to the substrate surface, the mask pattern formed in FIG. 4J does not lean or is not closed and becomes a good pattern.

Also, the mask pattern at this state includes a closed loop structure. Ends in the X direction of a pair of adjoining line patterns (part to be word line WL) are connected. Thus, above a whole surface of the semiconductor substrate, a resist is applied and a resist pattern is formed by the lithography technique in such a manner that a part other than an end in the X direction of a mask pattern for word line formation is covered. Then, by anisotropic etching processing of the RIE method or the like, the end in the X direction of the mask pattern for word line formation is removed. Accordingly, the mask pattern for word line formation arrayed regularly in a line-and-space manner can be acquired.

Then, as illustrated in FIG. 4K, with the mask pattern for word line formation as a mask, the object of processing including the control gate electrode film 14 is etched, for example, by the anisotropic etching of the RIE method or the like. Accordingly, word lines WL (stacked gate structure MG) extended in the X direction and arrayed at predetermined intervals in the Y direction, that is, in a line-and-space manner are formed. As described, by using the mask pattern vertical to the substrate surface, the object of processing is processed. Thus, a pattern formed on the object of processing is also formed well.

In the first embodiment, the embedment material 34 lower than the core material patterns 33 is formed around each core material pattern 33. On the embedment material 34, the shrink agent 35 including the block copolymer is applied. Also, the shrink agent 35 is heated and phase separation into the adherence portion 351 aggregated on the side of each core material pattern 33 and the sacrifice portion 352 aggregated near the center between the core material patterns 33 is performed. Then, by removing the embedment material 34 and the sacrifice portion 352 simultaneously, in a sectional surface vertical to the extended direction of the core material patterns 33, the eave-shaped core material pattern 33A an upper part of which has a wider width than a lower part thereof is formed. Then, by a sidewall transfer process using the core material pattern 33A, a semiconductor device is formed. By making the core material pattern 33A eave-shaped, the spacer film 36 is not closed or does not collapse when the core material pattern 33A is removed. That is, the spacer film 36 stands vertical to the substrate surface. As a result, by performing processing with the spacer film 36 as a mask, a pattern of the object of processing can be formed well.

Also, when a fine pattern is formed, a profile correction of a pattern including a structure, in an upper part of which an eave-shaped pattern is formed, such as what is illustrated in FIG. 4E becomes possible. Then, a pattern defect can be reduced when a pattern transfer is performed with this pattern as an etching mask. As a result, an efficiency percentage of a semiconductor device can be also increased.

### Second Embodiment

In the first embodiment, by adding an adherence portion to an upper part of the core material pattern, a shape an upper part of which has a wider width than a lower part thereof in a sectional surface vertical to an extended direction is realized. In the second embodiment, a different method to realize a shape an upper part of which has a wider width than a lower part thereof in a sectional surface vertical to an extended direction will be described.

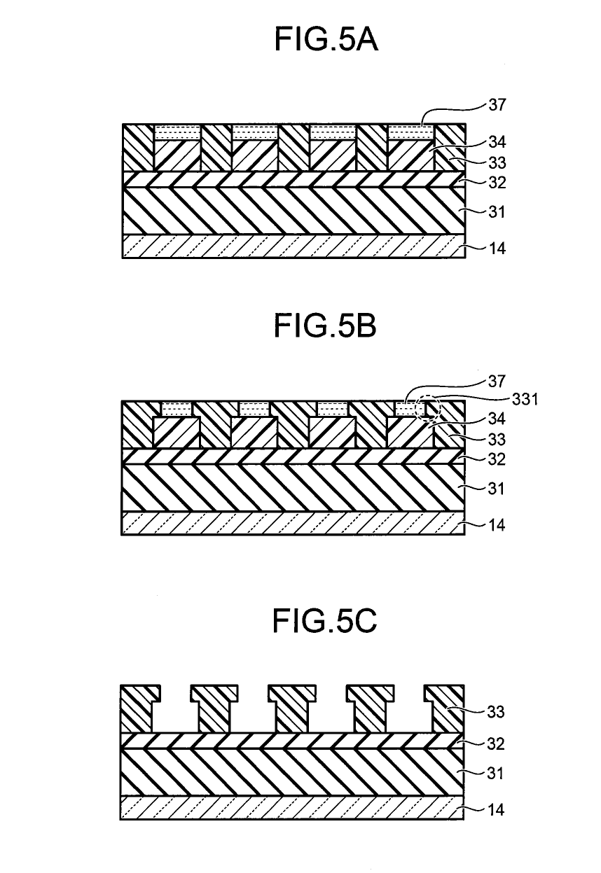

A pattern forming method and a method of manufacturing a semiconductor device according to the second embodiment are substantially the same with those of the first embodiment. In the following, a part different from the first embodiment will be described. FIG. 5A to FIG. 5C are partial sectional views schematically illustrating an example of the pattern forming method according to the second embodiment.

In FIG. 4C of the first embodiment, on the embedment material 34 between the core material patterns 33, a solution including a block copolymer is applied as the shrink agent 35. In the second embodiment, as illustrated in FIG. 5A, a narrowly-defined shrink agent 37 is applied as a shrink agent. The shrink agent 37 is a material a volume of which is reduced by heating.

After the shrink agent 37 is applied, an object of processing is heated in a hot plate of a nitrogen atmosphere at 240° C. for 60 seconds, for example. Accordingly, as illustrated in FIG. 5B, the shrink agent 37 is solidified while being cohesive to a surface of a core material pattern 33. Also, by heating, a volume of the shrink agent 37 is reduced. As a result, a part 331 of the core material pattern 33 which part is in touch with the shrink agent 37 is pulled toward the outside of the core material pattern 33. Then, in a sectional surface vertical to an extended direction of the core material pattern 33, an upper part of the core material pattern 33 has an eave-shape protruded in a lateral direction compared to a lower part thereof.

Then, as illustrated in FIG. 50, the embedment material 34 and the shrink agent 37 solidified near the center of an upper part thereof are selectively removed. For example, the embedment material 34 and the shrink agent 37 are removed by developing processing. Here, a solvent including an organic solvent which can dissolve polymethylmethacrylate (acrylic) included in the embedment material 34 and an organic material included in the shrink agent 37 is used as a developer.

As a result, the core material pattern 33 an upper part of which has an eave-shape is formed. Note that unlike the first embodiment, a whole part of the core material pattern 33 having an eave-shape includes the same material. Then, processing similar to the processing in and after FIG. 4F of the first embodiment is performed.

By the second embodiment, an effect similar to that of the first embodiment can also be acquired.

### Third Embodiment

In the first and second embodiments, by using a core material pattern, a line-and-space pattern is formed by a sidewall transfer process. In the third embodiment, a case where a trench for wiring line formation to form a line-and-space wiring line is formed by a damascene method will be described.

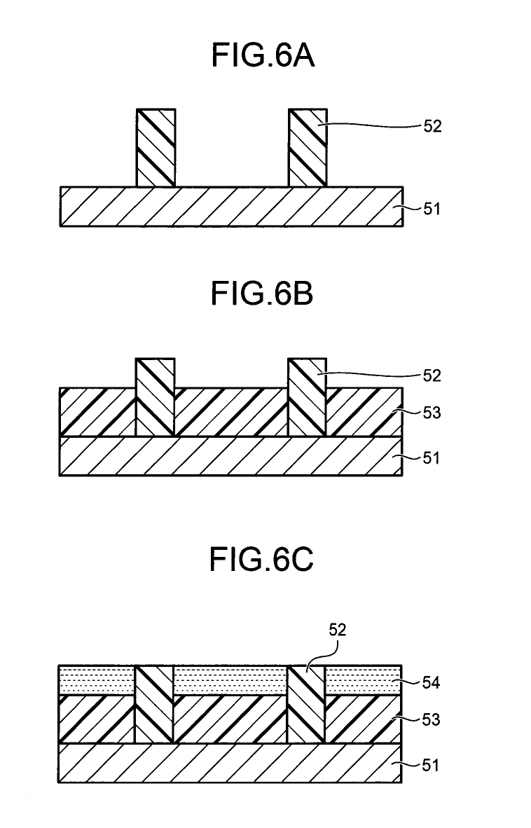

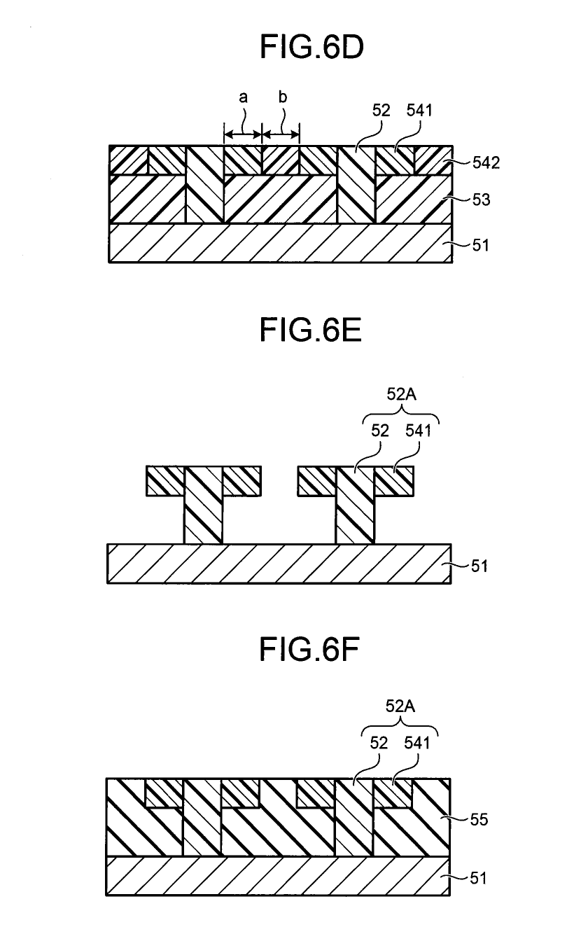

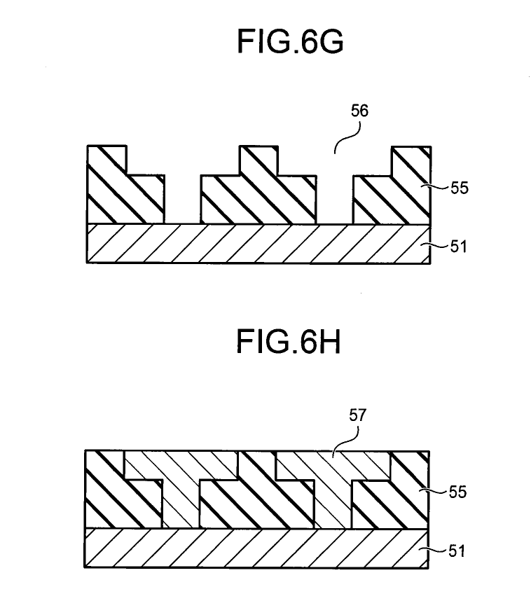

FIG. 6A to FIG. 6H are partial sectional views schematically illustrating an example of a pattern forming method according to the third embodiment. First, as illustrated in FIG. 6A, on a wiring line 51 extended in a first direction, a core material pattern 52 extended in a second direction which intersects with the first direction is formed. Specifically, on wiring lines 51 arranged at predetermined intervals in the second direction and on an insulation film (not illustrated) embedded between the wiring lines 51, a resist is applied. Then, by a lithography technique, patterning is performed in such a manner that a line-and-space pattern (periodic pattern), in which line patterns extended in the second direction are arranged at predetermined intervals in the first direction, is included. Accordingly, core material patterns 52 including a resist pattern are formed.

Then, as illustrated in FIG. 6B, on the wiring line 51 between the core material patterns 52 and on the insulation film (not illustrated), an embedment material 53 is formed. The embedment material 53 is preferably an organic material which can be removed in a developing process. For example, a polymer which is the same with a polymer chain, in a block copolymer formed in a later process, having low affinity for the core material patterns 52 can be used. As the embedment material 53, for example, PMMA can be used. The embedment material 53 is formed in such a manner that a height of the embedment material 53 becomes lower than a height of the core material patterns 52.

Then, as illustrated in FIG. 6C, on the embedment material 53 between the core material patterns 52, a shrink agent 54 is applied. In the third embodiment, as the shrink agent 54, a solution including a block copolymer is used. Specifically, by a method such as an ink jet method, a solution in which a block copolymer is dissolved is discharged on the core material patterns 52 and the embedment material 53 and spin rotation is performed. Accordingly, a block copolymer film is uniformly applied on the embedment material 53 between the core material patterns 52. Here, as the block copolymer, Ps-b-PMMA is used. According to a degree of projection in a lateral direction of an upper part of each core material pattern 52, a molecular weight and composition of the block copolymer can be determined.

Then, an object of processing is heated in a hot plate of a nitrogen atmosphere at 240° C. for 60 seconds, for example. Accordingly, as illustrated in FIG. 6D, in the block copolymer in the solution, phase separation into an adherence portion 541 aggregated to a side of each core material pattern 52 and a sacrifice portion 542 aggregated near a center between the core material patterns 52 is performed. When Ps-b-PMMA is used as the block copolymer, an aggregated polystyrene derivative becomes the adherence portion 541 and aggregated PMMA becomes the sacrifice portion 542. Note that it is assumed that a thickness of the adherence portion 541 adhered to each core material pattern 52 is a and a thickness of the sacrifice portion 542 is b. Here, a≠0 or b≠0.

Subsequently, as illustrated in FIG. 6E, the embedment material 53 and the sacrifice portion 542 aggregated near a center in an upper part thereof are selectively removed. For example, the embedment material 53 and the sacrifice portion 542 are removed by developing processing. Here, a solvent including an organic solvent which can dissolve polymethylmethacrylate (acrylic) included in the embedment material 53 and the sacrifice portion 542 is used as a developer.

As a result, by each core material pattern 52 and the adherence portion 541 remaining around the upper part thereof, a new core material pattern 52A is formed. In a sectional surface vertical to an extended direction of the new core material pattern 52A, an upper part has a wider width than a lower part. That is, the core material pattern 52A includes a structure in an upper part of which an eave-shaped pattern is formed.

Then, as illustrated in FIG. 6F, on the wiring line 51 and the insulation film (not illustrated), an interlayer insulation film 55 is formed. The interlayer insulation film 55 is formed to fill a space between the eave-shaped core material patterns 52A. Note that here, the interlayer insulation film 55 formed over upper surfaces of the core material patterns 52A is removed until the upper surfaces of the core material patterns 52A are exposed. Such removal of the interlayer insulation film 55 is performed by a method such as a chemical mechanical polishing (CMP) method.

Then, as illustrated in FIG. 6G, the core material patterns 52A are removed, for example, by organic material removing technique (asher) using an oxygen radical. Since the core material patterns 52A are organic films, ashing is performed by the oxygen radical. As a result, in the interlayer insulation film 55, trenches 56 for wiring line formation remaining in a state substantially vertical to a substrate surface are arranged at predetermined intervals in the first direction.

Then, as illustrated in FIG. 6H, after a barrier metal film and a seed film (not illustrated) are formed in the trenches 56 for wiring line formation, a metal film is formed by a plating method. The barrier metal film prevents diffusion of metal to be a metal wiring line. The seed film becomes a conductor layer during plating processing. Accordingly, in each of the trenches 56 for wiring line formation in the interlayer insulation film 55, a second wiring line including a metal film is formed. Note that as the metal film, Cu, Al, W, or the like can be used. By what has been described above, the pattern forming method according to the third embodiment ends.

Note that in the above description, similarly to the case of the first embodiment, a case of forming the adherence portion 541 by using a solution including a block copolymer has been described as an example. However, similarly to the case of the second embodiment, the shrink agent 54 may be used to pull an upper part of the core material pattern 52 toward the outside and to form an eave-shaped structure.

In the third embodiment, the embedment material 53 lower than the core material patterns 52 is formed around each core material pattern 52 and the shrink agent 54 including a block copolymer is applied on the embedment material 53. Also, in the shrink agent 54, phase separation into the adherence portion 541 aggregated on the side of each core material pattern 52 and the sacrifice portion 542 aggregated near the center between the core material patterns 52 is performed. Then, by removing the embedment material 53 and the sacrifice portion 542 simultaneously, in a sectional surface vertical to the extended direction, the eave-shaped core material pattern 52A an upper part of which has a wider width than a lower part thereof is formed. Then, a periphery of the core material pattern 52A is surrounded by the interlayer insulation film 55 and the core material pattern 52A is removed, whereby, the trench 56 for wiring line formation is formed. Then, a metal film is embedded into the trench 56 for wiring line formation, whereby a second wiring line 57 is formed. Accordingly, in the interlayer insulation film 55 formed during the damascene processing, the trench 56 for wiring line formation which stands vertically to the substrate surface is formed. As a result, the second wiring line 57 formed in the trench 56 for wiring line formation does not collapse or is not closed. Thus, an efficiency percentage of a semiconductor device can be increased.

Note that in the above description, a pattern in which linear line patterns are arranged vertically to an extended direction at predetermined intervals has been described as an example of a line-and-space pattern. However, the line-and-space pattern is not necessarily in a linear manner. A lead wiring line, an arranged wiring line, and a U-shaped wiring line being arranged in a direction orthogonal to an extended direction can be also considered as line-and-space patterns. Also, even when there is a pattern to connect parallel line patterns, a part excluding the connection pattern can be considered as a line pattern.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method comprising:
forming linear core material patterns arranged vertically to an extended direction at predetermined intervals above an object of processing;
embedding an embedment material between the core material patterns in such a manner that a height thereof becomes lower than a height of each of the core material patterns;
supplying a shrink agent on the embedment material between the core material patterns;
heating the shrink agent to solidify the shrink agent;
removing at least a part of the solidified shrink agent and the embedment material;
forming a spacer film above the object of processing above which the core material patterns are formed;
etching-back the spacer film in such a manner that upper surfaces of the core material patterns are exposed; and
forming a spacer pattern including the spacer film by removing the core material patterns,
wherein in the removal of the solidified shrink agent and the embedment material, the solidified shrink agent which is formed in such a manner that a width of the spacer pattern becomes narrow in a region corresponding to a position where the shrink agent is supplied, in a sectional surface vertical to an extended direction of the spacer pattern is removed.

2. The pattern forming method according to claim 1, wherein the shrink agent is a block copolymer,
in the heating of the shrink agent, phase separation into an adherence portion which is one polymer chain of the block copolymer aggregated on a side of each of the core material patterns and a sacrifice portion which is the other polymer chain aggregated near a center between the core material patterns is performed, and
in the removing of the shrink agent and the embedment material, the sacrifice portion and the embedment material are removed.

3. The pattern forming method according to claim 2, wherein the embedment material includes a same material with the sacrifice portion of the block copolymer.

4. The pattern forming method according to claim 2, wherein in the removing of the solidified shrink agent and the embedment material, the embedment material and the sacrifice portion of the block copolymer are removed by developing.

5. The pattern forming method according to claim 4, wherein each of the core material patterns is a resist,
the block copolymer is polystyrene-polymethylmethacrylate,
the adherence portion includes an aggregation of polymethylmethacrylate,
the sacrifice portion includes an aggregation of polystyrene, and
the embedment material is polystyrene.

6. The pattern forming method according to claim 1, wherein in the heating of the shrink agent, the shrink agent is made to shrink while being solidified and an interface between each of the core material patterns and the solidified shrink agent is pulled in a shrinkage direction of the shrink agent in such a manner that the upper part of each of the core material patterns becomes protruded compared to the lower part thereof.

7. The pattern forming method according to claim 6, wherein in the removing of the solidified shrink agent and the embedment material, the embedment material and the solidified shrink agent are removed by developing.

8. A pattern forming method comprising:
forming, on first wiring lines extended in a first direction and arranged via an insulation film at predetermined intervals in a second direction which intersects with the first direction, linear core material patterns extended in the second direction and arranged at predetermined intervals in the first direction;
embedding an embedment material between the core material patterns in such a manner that a height thereof becomes lower than a height of each of the core material patterns;
supplying a shrink agent on the embedment material between the core material patterns;
heating the shrink agent to solidify the shrink agent;
removing the solidified shrink agent and the embedment material;
embedding an interlayer insulation film between the core material patterns; and
removing the core material patterns,
wherein in the removal of the solidified shrink agent and the embedment material, a solidified shrink agent which is formed in such a manner that a width of the interlayer insulation film becomes narrow in a region corresponding to a position where the shrink agent is supplied, in a sectional surface vertical to an extended direction of the core material patterns is removed.

9. The pattern forming method according to claim 8, wherein the shrink agent is a block copolymer,
in the heating of the shrink agent, phase separation into an adherence portion which is one polymer chain of the block copolymer aggregated on a side of each of the core material patterns and a sacrifice portion which is the other polymer chain aggregated near a center between the core material patterns is performed, and
in the removing of the shrink agent and the embedment material, the sacrifice portion and the embedment material are removed.

10. The pattern forming method according to claim 9, wherein in the removing of the shrink agent and the embedment material, the embedment material and the sacrifice portion of the block copolymer are removed by developing.

11. The pattern forming method according to claim 10, wherein each of the core material patterns is a resist,
the block copolymer is polystyrene-polymethylmethacrylate,
the adherence portion includes an aggregation of polymethylmethacrylate,
the sacrifice portion includes an aggregation of polystyrene, and
the embedment material is polystyrene.

12. The pattern forming method according to claim 8, wherein in the heating of the shrink agent, the shrink agent is made to shrink while being solidified and an interface between each of the core material patterns and the solidified shrink agent is pulled in a shrinkage direction of the shrink agent in such a manner that the upper part of each of the core material patterns becomes protruded compared to the lower part thereof.

13. A method of manufacturing a semiconductor device including word lines which configure memory cells and are extended in a first direction and arranged at predetermined intervals in a second direction orthogonal to the first direction, the method comprising:
forming linear core material patterns extended in the first direction and arranged at predetermined intervals in the second direction above an object of processing;
embedding an embedment material between the core material patterns in such a manner that a height thereof becomes lower than a height of each of the core material patterns;
supplying a shrink agent on the embedment material between the core material patterns;
heating the shrink agent to solidify the shrink agent;
removing at least a part of the solidified shrink agent and the embedment material;
forming a spacer film on the object of processing on which the core material patterns are formed;
etching-back the spacer film in such a manner that an upper surface of each of the core material patterns is exposed;
removing the core material patterns to form a spacer pattern including the spacer film; and
processing the object of processing with the spacer pattern as a mask to form a wiring line pattern including the word lines,
wherein, in the removal of the solidified shrink agent and the embedment material, the solidified shrink agent which is formed in such a manner that a width of the spacer pattern becomes narrow in a region corresponding to a position where the shrink agent is supplied, in a sectional surface vertical to an extended direction of the spacer pattern is removed.

14. The method of manufacturing a semiconductor device according to claim 13, further comprising:
forming, before the forming of the core material patterns, a tunnel insulation film and a floating gate electrode film on a semiconductor substrate;
forming trenches arranged at predetermined intervals in the first direction and extended in the second direction from the floating gate electrode film to the semiconductor substrate;
embedding an element isolating insulation film into the trenches;
forming an inter-electrode insulation film on the element isolating insulation film and the floating gate electrode film;
forming a control gate electrode film to be the object of processing on the inter-electrode insulation film, wherein
in the forming of the core material patterns, the core material patterns are formed on the control gate electrode film.

15. The method of manufacturing a semiconductor device according to claim 13, wherein the shrink agent is a block copolymer,
in the heating of the shrink agent, phase separation into an adherence portion which is one polymer chain of the block copolymer aggregated on a side of each of the core material patterns and a sacrifice portion which is the other polymer chain aggregated near a center between the core material patterns is performed, and
in the removing of the shrink agent and the embedment material, the sacrifice portion and the embedment material are removed.

16. The method of manufacturing a semiconductor device according to claim 15, wherein in the removing of the shrink agent and the embedment material, the embedment material and the sacrifice portion of the block copolymer are removed by developing.

17. The method of manufacturing a semiconductor device according to claim 16, wherein each of the core material patterns is a resist,
the block copolymer is polystyrene-polymethylmethacrylate,
the adherence portion includes an aggregation of polymethylmethacrylate,
the sacrifice portion includes an aggregation of polystyrene, and
the embedment material is polystyrene.

18. The method of manufacturing a semiconductor device according to claim 13, wherein in the heating of the shrink agent, the shrink agent is made to shrink while being solidified and an interface between each of the core material patterns and the solidified shrink agent is pulled in a shrinkage direction of the shrink agent in such a manner that the upper part of each of the core material patterns becomes protruded compared to the lower part thereof.

19. The method of manufacturing a semiconductor device according to claim 18, wherein in the removing of the solidified shrink agent and the embedment material, the embedment material and the solidified shrink agent are removed by developing.
